(19) United States
(12) Patent Application Publication
(10) Pub. No.: US 2026/0188967 A1
(43) Pub. Date: Jul. 2, 2026

(54) OPTICAL MODULE

(71) Applicant: Mitsubishi Electric Corporation, Tokyo (JP)

(72) Inventors: Junichi SUZUKI, Tokyo (JP); Kei MASUYAMA, Tokyo (JP); Koichi NAKAMURA, Tokyo (JP)

(73) Assignee: Mitsubishi Electric Corporation, Tokyo (JP)

(21) Appl. No.: 19/544,626

(22) Filed: Feb. 19, 2026

Related U.S. Application Data
(63) Continuation of application No. PCT/JP2023/035048, filed on Sep. 27, 2023.

(51) Int. Cl. H01S 5/00; H01S 5/02212; H01S 5/02345; H01S 5/042

(52) U.S. Cl. CPC H01S 5/0014; H01S 5/02212; H01S 5/02345; H01S 5/04256

(57) ABSTRACT

An optical module includes: a semiconductor laser having a light emission coupler to emit a rear laser beam along with emission of a front laser beam from a front end; and an optical monitor having a light coupling coupler to receive and couple the rear laser beam emitted from the light emission coupler. The semiconductor laser and the optical monitor are superimposed in such a manner that the light emission coupler and the light coupling coupler face each other.

### CROSS REFERENCE TO RELATED APPLICATION

This application is a Continuation of PCT International Application No. PCT/JP2023/035048, filed on Sep. 27, 2023, which is hereby expressly incorporated by reference into the present application.

### TECHNICAL FIELD

The present disclosure relates to optical modules.

### BACKGROUND ART

One of methods for increasing the capacity of optical communication systems is a digital coherent communication scheme. The digital coherent communication scheme is a scheme in which many channels are transmitted by modulating not only the intensity of light, but also the phase with signals. To extract phase information of light, optical interference phenomena are used. Accordingly, both the light source of a transmitter to send a signal and local oscillator light which is interference light at a receiver to receive the signal need to have their wavelengths controlled precisely.

A single mode laser is used as the light source. Although a single mode laser oscillates at a single wavelength, the oscillation wavelength and optical output intensity vary undesirably depending on manufacturing errors and environment temperature in some cases. Because of this, a wavelength locker and an optical intensity monitor for wavelength control are essential in a light source module for digital coherent communication on which a single mode laser is mounted. In particular, the oscillation wavelength is required to be controlled precisely within a tolerance of 0.1 nm or less. In view of this, Patent Literature 1 discloses an optical module to control the oscillation wavelength of a laser highly precisely.

### CITATION LIST

### Patent Literatures

Patent Literature 1: JP 2003-69130 A.

Patent Literature 2: Japanese Patent No. 7224555.

### SUMMARY OF INVENTION

### Technical Problem

The optical module disclosed in Patent Literature 1 includes a laser and an etalon. The transmittance of the etalon varies depending on the wavelength of light to be transmitted. Because of this, the optical module disclosed in Patent Literature 1 can allow a rear laser beam of the laser to be transmitted to the etalon, and monitor the intensity of the rear laser beam using a light receiving element. As a result, the optical module disclosed in Patent Literature 1 is capable of sensing variations in the oscillation wavelength of the laser.

However, the optical module disclosed in Patent Literature 1 is provided with a temperature control element for each of the laser and the etalon, which results in an increase in the module size. In addition, the optical module disclosed in Patent Literature 1 requires a plurality of components to collimate light incident on the etalon. Because of this, there is a risk that the optical module disclosed in Patent Literature 1 incurs increased manufacturing costs.

In contrast, an optical module disclosed in Patent Literature 2 includes a planar waveguide-type optical monitor for the purpose of reducing the number of components and downsizing. At this time, at a pedestal portion included in the optical module, the mounting surface of a laser and the mounting surface of the optical monitor are mutually different surfaces. Because of this, to highly efficiently couple a rear laser beam of the laser to the optical monitor, the laser and the optical monitor need to be mounted highly precisely on the respective mounting surfaces.

The present disclosure has been made in order to solve the problem described above, and an object thereof is to provide an optical module to enable highly efficient coupling of a rear laser beam emitted from a laser output unit to an optical monitor, without providing a mounting surface dedicated for an optical monitor on a pedestal portion.

### Solution to Problem

An optical module according to the present disclosure includes: a laser outputter having a light emission coupler to emit a rear laser beam along with emission of a front laser beam from a front end; and an optical monitor having a light coupling coupler to receive and couple the rear laser beam emitted from the light emission coupler, in which the laser outputter and the optical monitor are superimposed in such a manner that the light emission coupler and the light coupling coupler face each other.

### Advantageous Effects of Invention

The present disclosure enables highly efficient coupling of a rear laser beam emitted from a laser output unit to an optical monitor, without providing a mounting surface dedicated for the optical monitor on a pedestal portion.

### BRIEF DESCRIPTION OF DRAWINGS

FIG. 1 is a vertical cross-sectional view of a state where a cap of an optical module according to a first embodiment is removed.

FIG. 2 is a perspective view of the optical module according to the first embodiment.

FIG. 3 is an enlarged view of main parts depicted in FIG. 1.

FIG. 4 is a plan view of a state before a semiconductor laser and an optical monitor are stacked on each other.

FIG. 5 is a plan view of a state where the semiconductor laser and the optical monitor are stacked on each other.

FIG. 6 is a plan view of a state before an optical amplifier and an optical monitor are stacked on each other in an optical module according to a second embodiment.

FIG. 7 is a plan view of a state where the optical amplifier and the optical monitor are stacked on each other in the optical module according to the second embodiment.

FIG. 8 is an enlarged cross-sectional view of main parts of an optical module according to a third embodiment.

FIG. 9 is a plan view of a state before a semiconductor laser and an optical monitor are stacked on each other in the optical module according to the third embodiment.

FIG. 10 is a plan view of a state where the semiconductor laser and the optical monitor are stacked on each other in the optical module according to the third embodiment.

FIG. 11 is a plan view of a state before an optical amplifier and an optical monitor are stacked on each other in an optical module according to a fourth embodiment.

FIG. 12 is a plan view of a state where the optical amplifier and the optical monitor are stacked on each other in the optical module according to the fourth embodiment.

### DESCRIPTION OF EMBODIMENTS

Hereinbelow, embodiments for implementing the present disclosure are explained with reference to the attached drawings in order to explain the present disclosure in more detail.

### First Embodiment

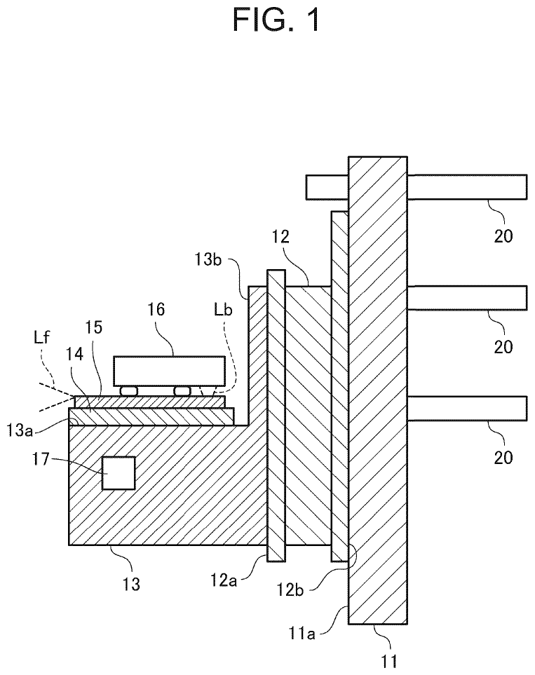

An optical module according to a first embodiment is explained using FIGS. 1 to 5.

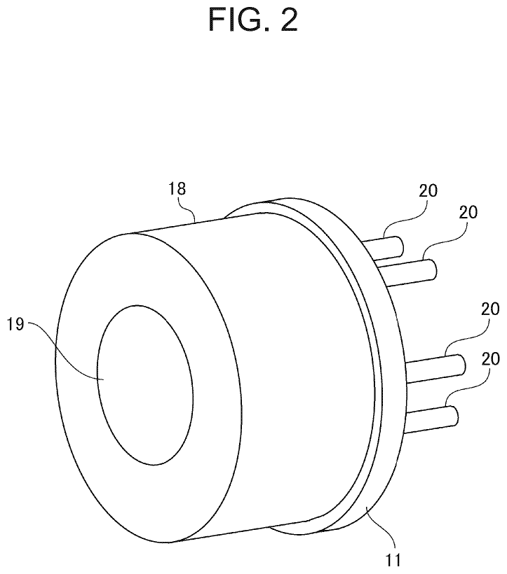

FIG. 1 is a vertical cross-sectional view of a state where a cap 18 of the optical module according to the first embodiment is removed. FIG. 2 is a perspective view of the optical module according to the first embodiment.

For example, the optical module according to the first embodiment is an optical module for digital coherent communication. As depicted in FIGS. 1 and 2, the optical module according to the first embodiment includes a stem 11, a temperature controller 12, a pedestal portion 13, a semiconductor laser submount (hereinbelow, referred to as submount) 14, a semiconductor laser 15, a planar waveguide type optical monitor (hereinbelow, referred to as optical monitor) 16, a thermistor 17, the cap 18, a window member 19, and a plurality of pins 20. Note that the semiconductor laser 15 is included in a laser output unit.

The stem 11 is formed into a disk shape. For example, the stem 11 includes a conductive material such as a metal material. In addition, the stem 11 has a main surface 11a. The main surface 11a is a flat vertical surface, and is included in a mounting surface for the temperature controller 12. Note that the external shape of the stem 11 may be elliptical, triangular, rectangular, or the like.

The temperature controller 12 is fixed to the stem 11. The temperature controller 12 has a left-side surface 12a and a right-side surface 12b. The left-side surface 12a and the right-side surface 12b are arranged to be parallel to the main surface 11a. Among them, the right-side surface 12b is mounted on the main surface 11a.

The temperature controller 12 controls the temperatures of the semiconductor laser 15 and the optical monitor 16 via the pedestal portion 13. Specifically, upon being supplied with a control current, the temperature controller 12 heats or cools the semiconductor laser 15 and the optical monitor 16 according to the direction of the control current. At this time, upon receiving heat generated from the temperature controller 12, the stem 11 releases the heat to the outside. For example, the temperature controller 12 is a thermo-electric cooler (TEC: Thermo-electric cooler) including a Peltier element or the like.

The pedestal portion 13 is mounted on the left-side surface 12a of the temperature controller 12. The pedestal portion 13 has an L-shape when seen from the side of the optical module. Because of this, the pedestal portion 13 has a mounting surface 13a, which is a horizontal surface, and a vertical surface 13b. The mounting surface 13a and the vertical surface 13b are arranged to be orthogonal to each other. The pedestal portion 13 transfers heat generated from the temperature controller 12 to the semiconductor laser 15 and the optical monitor 16. For example, the pedestal portion 13 includes a metal material that excels in thermal conductivity.

The submount 14 is mounted on the mounting surface 13a of the pedestal portion 13. For example, the submount 14 includes a base including an aluminum nitride dielectric having a patterned metal wiring layer on its surface.

The semiconductor laser 15 is mounted on the mounting surface 13a of the pedestal portion 13 via the submount 14. Furthermore, the optical monitor 16 is mounted on the semiconductor laser 15. Note that details of the mounting of the optical monitor 16 onto the semiconductor laser 15 are described later.

Accordingly, the pedestal portion 13 transfers heat generated from the temperature controller 12, and adjusts the temperatures of the semiconductor laser 15 and the optical monitor 16 through the submount 14. At this time, the semiconductor laser 15 and the optical monitor 16 whose temperatures are adjusted by the temperature controller 12 are stacked on the one mounting surface 13a. Because of this, the optical module according to the first embodiment allows for a reduction in the area occupied by the semiconductor laser 15 and the optical monitor 16 on the mounting surface 13a. As a result, the optical module according to the first embodiment allows for a reduction in the size and weight of the pedestal portion 13.

The semiconductor laser 15 is a single wavelength semiconductor laser, or a so-called single mode laser to oscillate at a single wavelength. The semiconductor laser 15 emits a front laser beam Lf from the front end surface (emission surface), and emits a rear laser beam Lb from the upper surface. The front laser beam Lf is used for optical communication. The rear laser beam Lb is monitored by being emitted toward the optical monitor 16. The optical axis of the front laser beam Lf and the optical axis of the rear laser beam Lb are orthogonal to each other.

The thermistor 17 is provided on the pedestal portion 13. The thermistor 17 measures the temperature of heat transferred from the temperature controller 12 to the semiconductor laser 15 and the optical monitor 16.

The cap 18 is formed into a lidded cylindrical shape. The open end of the cap 18 is fixed to the main surface 11a of the stem 11. The cap 18 is provided to cover the temperature controller 12, the pedestal portion 13, the submount 14, the semiconductor laser 15, the optical monitor 16, and the thermistor 17 from the outside. For example, the cap 18 includes a metal material or a resin material.

The window member 19 is fitted into the lid portion of the cap 18. The window member 19 condenses and transmits the front laser beam Lf emitted from the semiconductor laser 15. For example, the window member 19 is a planar glass or a lens.

The plurality of pins 20 are electrically connected to the temperature controller 12, the semiconductor laser 15, and the optical monitor 16. Each pin 20 penetrates and is supported by the stem 11. At this time, each pin 20 is insulated from the stem 11.

The optical module according to the first embodiment includes a control unit (not illustrated). The temperature controller 12, the semiconductor laser 15, and the optical monitor 16 are controlled by the control unit. The control unit exchanges signals with each of the temperature controller 12, the semiconductor laser 15, and the optical monitor 16 through the corresponding pin 20. In addition, the control unit controls, through the corresponding pins 20, the currents and voltages supplied to the temperature controller 12, the semiconductor laser 15, and the optical monitor 16, and controls the optical intensity and wavelength of the front laser beam Lf emitted from the semiconductor laser 15.

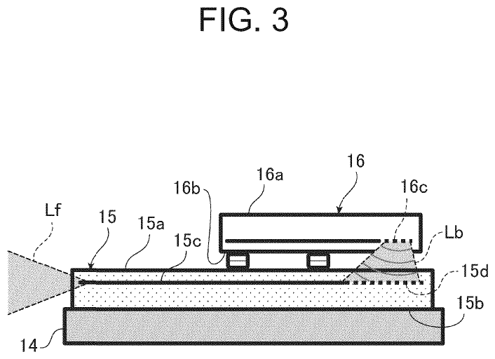

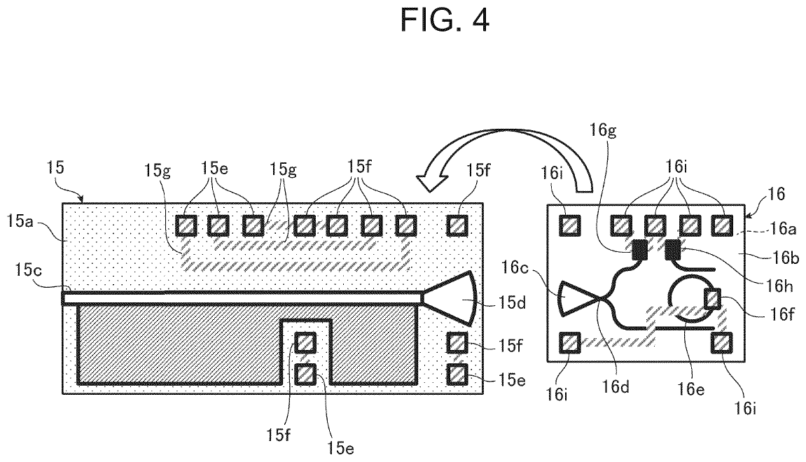

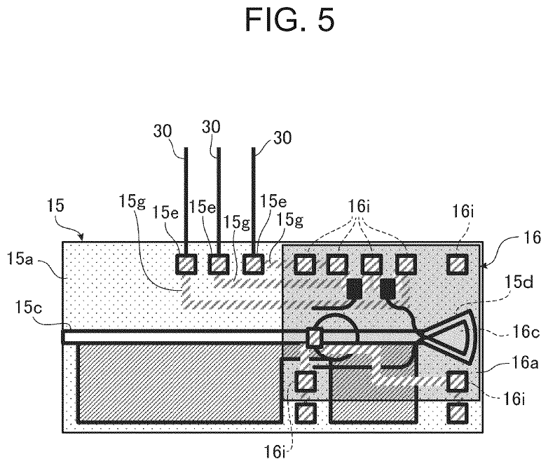

Next, the mounting of the optical monitor 16 onto the semiconductor laser 15 is explained using FIGS. 3 to 5. FIG. 3 is an enlarged view of main parts depicted in FIG. 1. FIG. 4 is a plan view of a state before the semiconductor laser 15 and the optical monitor 16 are stacked on each other. FIG. 5 is a plan view of a state where the semiconductor laser 15 and the optical monitor 16 are stacked on each other.

As depicted in FIG. 3, the semiconductor laser 15 has an upper surface 15a and a lower surface 15b. The upper surface 15a and the lower surface 15b are surfaces that are positioned on opposite sides in the thickness direction of the semiconductor laser 15. In addition, the optical monitor 16 has an upper surface 16a and a lower surface 16b. The upper surface 16a and the lower surface 16b are surfaces that are positioned on opposite sides in the thickness direction of the optical monitor 16.

The lower surface 15b of the semiconductor laser 15 is mounted on the upper surface of the submount 14. The lower surface 16b of the optical monitor 16 is mounted on the upper surface 15a of the semiconductor laser 15. That is, the lower surface 15b of the semiconductor laser 15 is a mounting surface for the upper surface of the submount 14. The lower surface 16b of the optical monitor 16 is a mounting surface for the upper surface 15a of the semiconductor laser 15.

As depicted in FIG. 4, the semiconductor laser 15 has a laser stripe 15c, a light emission coupler 15d, a plurality of electrodes 15e and 15f, and a plurality of wiring lines 15g. The laser stripe 15 c, the light emission coupler 15d, the plurality of electrodes 15e and 15f, and the plurality of wiring lines 15g are provided on the same surface, which is the upper surface 15a.

The laser stripe 15c emits the front laser beam Lf. The light emission coupler 15d emits the rear laser beam Lb. The light emission coupler 15d is connected to the rear end of the elongated laser stripe 15c. In this manner, by having the light emission coupler 15d, the semiconductor laser 15 can output the rear laser beam Lb from the upper surface 15a. For example, the light emission coupler 15d is a grating coupler.

The electrodes 15e and 15f are arranged around the laser stripe 15c and the light emission coupler 15d. Note that the electrodes 15e and 15f are included in laser-side electrodes. In addition, the electrodes 15e are included in wire bonding laser-side electrodes, and the electrodes 15f are included in connection laser-side electrodes.

As described in detail later, the electrodes 15e are arranged in an area not covered with the optical monitor 16 when the optical monitor 16 is mounted on the semiconductor laser 15. In addition, the electrodes 15f are covered with the optical monitor 16, and are electrically connected to electrodes 16i of the optical monitor 16 when the optical monitor 16 is mounted on the semiconductor laser 15.

The wiring lines 15g electrically connect respective pairs of the electrodes 15e and the electrodes 15f. As described in detail later, the electrodes 15f connected to the wiring lines 15g correspond to electrodes 16 i electrically connected to a first photoreceiver 16g and a second photoreceiver 16h in the electrodes 16i of the optical monitor 16.

As depicted in FIG. 4, the optical monitor 16 has a light coupling coupler 16c, an optical splitter 16d, an optical filter 16e, a heater 16f, the first photoreceiver 16g, the second photoreceiver 16h, and a plurality of the electrodes 16i. The light coupling coupler 16c, the optical splitter 16d, the optical filter 16e, the heater 16f, the first photoreceiver 16g, the second photoreceiver 16h, and the plurality of electrodes 16i are provided on the same surface, which is the lower surface 16b. Optical waveguides (not illustrated) connect the light coupling coupler 16c and the optical splitter 16d, the optical splitter 16d and the optical filter 16e, the optical filter 16e and the heater 16f, the heater 16f and the first photoreceiver 16g, and the optical splitter 16d and the second photoreceiver 16h.

For example, the optical monitor 16 is a planar waveguide type optical monitor formed by integrating, on a surface of a silicon (Si) substrate, the light coupling coupler 16c, the optical splitter 16d, the optical filter 16e, the heater 16f, the first photoreceiver 16g, the second photoreceiver 16h, the plurality of electrodes 16i, and the optical waveguides.

The light coupling coupler 16c couples the rear laser beam Lb incident perpendicularly on the lower surface 16b of the optical monitor 16, and transmits the rear laser beam Lb to the optical splitter 16d. For example, the light coupling coupler 16c is a grating coupler.

The optical splitter 16d receives the rear laser beam Lb transmitted from the light coupling coupler 16c, and splits the received rear laser beam Lb into two laser beams.

The first photoreceiver 16g receives a first laser beam obtained by the splitting by the optical splitter 16d, and photo-electrically converts the received first laser beam. In addition, after photo-electrically converting the first laser beam, the first photoreceiver 16g outputs a current corresponding to the optical intensity of the first laser beam. The first photoreceiver 16g functions as an optical power monitor of the semiconductor laser 15 because the first photoreceiver 16g converts the optical intensity of the rear laser beam Lb coupled by the light coupling coupler 16c directly into a current. Furthermore, the first photoreceiver 16g is electrically connected to corresponding electrodes 16i. Because of this, it becomes possible for the first photoreceiver 16g to output, to the electrodes 16i, the current corresponding to the optical intensity of the first laser beam.

The optical filter 16e receives a second laser beam obtained by the splitting by the optical splitter 16d, and transmits the received second laser beam to the second photoreceiver 16h via the optical filter 16e. For example, the optical filter 16e exhibits temperature dependence with respect to the wavelength of light. Because of this, the peak value of the wavelength of a laser beam output from the optical filter 16e shifts toward longer-wavelength side as the temperature of the optical filter 16e increases. For example, the optical filter 16e is a ring resonator with a phase shifter or a Mach-Zehnder interferometer with a phase shifter.

The second photoreceiver 16h converts a laser beam filtered by the optical filter 16e (a laser beam resonant with the rear laser beam Lb) into a current. At this time, when the wavelength of the rear laser beam Lb varies, the current value output from the second photoreceiver 16h also varies. In addition, the second photoreceiver 16h is electrically connected to corresponding electrodes 16i. Because of this, it becomes possible for the second photoreceiver 16h to output, to the electrodes 16i, a current corresponding to the optical intensity of the second laser beam.

The electrodes 16i are arranged around the light coupling coupler 16c, the optical splitter 16d, the optical filter 16e, the heater 16f, the first photoreceiver 16g, and the second photoreceiver 16h. The electrodes 16i correspond to the electrodes 15f. Note that the electrodes 16i are included in monitor-side electrodes and connection monitor-side electrodes.

Accordingly, in a case where the optical monitor 16 is mounted on the semiconductor laser 15, as depicted in FIG. 4, first, the semiconductor laser 15 is oriented in such a manner that the upper surface 15a faces upward, and the optical monitor 16 is oriented in such a manner that the lower surface 16b faces upward. Next, as depicted in FIGS. 4 and 5, from such states, the optical monitor 16 is flipped upside down in such a manner that the upper surface 16a and the lower surface 16b are reversed vertically. Thereby, the lower surface 16b is mounted on the upper surface 15a of the semiconductor laser 15.

At this time, the light emission coupler 15d and the light coupling coupler 16c face each other. Because of this, the light coupling coupler 16c can receive and couple the rear laser beam Lb emitted from the light emission coupler 15d. In addition, the electrodes 15f and the electrodes 16i face each other, respectively. The electrodes 15f and the electrodes 16i are joined with each other using gold bumps, solder bumps, or the like. Because of this, the optical module according to the first embodiment can electrically connect the semiconductor laser 15 and the optical monitor 16.

Since the optical monitor 16 is mounted in a flipped orientation, wire bonding to the electrodes 16i electrically connecting to the first photoreceiver 16g and the second photoreceiver 16h is not possible. That is, a current corresponding to the optical intensity of a laser beam cannot be extracted from the electrodes 16i electrically connected to the first photoreceiver 16g and the second photoreceiver 16h.

However, in the optical module according to the first embodiment, the wiring lines 15g link the electrodes 15f electrically connected to the electrodes 16i and the electrodes 15e not covered with the optical monitor 16. Because of this, the optical module according to the first embodiment can extract a current corresponding to the optical intensity of a laser beam from the electrodes 15e not covered with the optical monitor 16 by bonding wires 30 to the electrodes 15e.

Therefore, the optical module according to the first embodiment can sense the optical output power and oscillation wavelength of the semiconductor laser 15 by measuring the current value output from the first photoreceiver 16g and the current value output from the second photoreceiver 16h.

Here, in the optical module disclosed in Patent Literature 2, the distance between the semiconductor laser and the optical monitor whose installation positions are on mutually different mounting surfaces needs to be kept at approximately several hundred μm in such a manner that a semiconductor laser and the optical monitor do not contact each other at the time of the mounting. Such mounting hinders the efficiency enhancement of light coupling in the optical monitor. In addition, in the optical module disclosed in Patent Literature 2, there are variations in the thickness of each of a submount and the semiconductor laser, variations in the emission direction of a rear laser beam from the semiconductor laser due to cleavage errors, and the like in some cases. In this case, in the optical module disclosed in Patent Literature 2, it is difficult to efficiently and stably couple the rear laser beam with the optical monitor.

In contrast, in the optical module according to the first embodiment, the upper surface 15a of the semiconductor laser 15 and the lower surface 16b of the optical monitor 16 are connected in such a manner that the upper surface 15a and the lower surface 16b face each other and overlap. Because of this, in the optical module according to the first embodiment, the semiconductor laser 15 and the optical monitor 16 can be brought close to each other to within, for example, approximately several tens of μm, without concern for mutual contact. As a result, the optical module according to the first embodiment can enhance the light coupling efficiency of the optical monitor 16, without providing the mounting surface for the optical monitor 16 on the pedestal portion 13.

As described above, the optical module according to the first embodiment includes: the semiconductor laser 15 having the light emission coupler 15d to emit the rear laser beam Lb along with the emission of the front laser beam Lf from its front end; and the optical monitor 16 having the light coupling coupler 16c to receive and couple the rear laser beam Lb emitted from the light emission coupler 15d, and the semiconductor laser 15 and the optical monitor 16 are superimposed in such a manner that the light emission coupler 15d and the light coupling coupler 16c face each other. Because of this, the optical module according to the first embodiment enables highly efficient coupling of the rear laser beam Lb emitted from the semiconductor laser 15 to the optical monitor 16, without providing a mounting surface dedicated for the optical monitor on the pedestal portion 13.

In addition, the optical module according to the first embodiment allows for a reduction in the size and weight of the pedestal portion 13 since the semiconductor laser 15 and the optical monitor 16 are connected in such a manner that the semiconductor laser 15 and the optical monitor 16 face each other and overlap.

### Second Embodiment

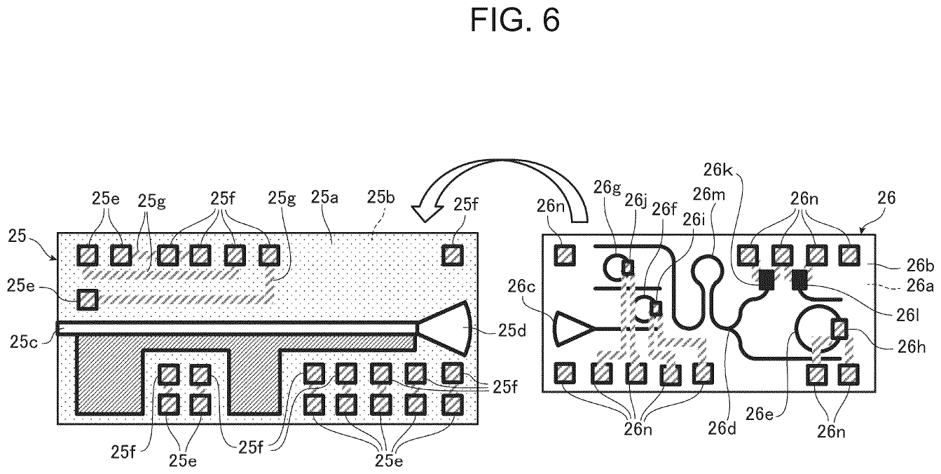

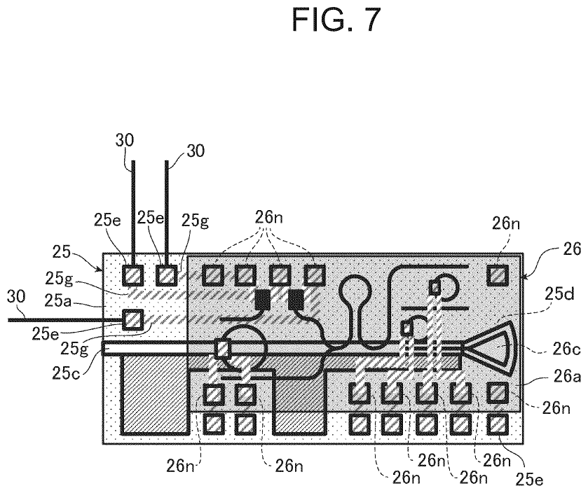

An optical module according to a second embodiment is explained using FIGS. 6 and 7.

FIG. 6 is a plan view of a state before an optical amplifier 25 and a reflective filter integrated optical monitor (hereinbelow, referred to as optical monitor) 26 are stacked on each other in the optical module according to the second embodiment. FIG. 7 is a plan view of a state where the optical amplifier 25 and the optical monitor 26 are stacked on each other in the optical module according to the second embodiment. Note that configurations having functions similar to those of the configurations explained in the first embodiment described above are given identical reference signs, and explanations thereof are omitted.

The optical module according to the second embodiment includes the optical amplifier 25 and the optical monitor 26 instead of the semiconductor laser 15 and the optical monitor 16 in the optical module according to the first embodiment. Note that the optical amplifier 25 is included in a laser output unit.

As depicted in FIG. 6, the optical amplifier 25 has an upper surface 25a and a lower surface 25b. The upper surface 25a and the lower surface 25b are surfaces that are positioned on opposite sides in the thickness direction of the optical amplifier 25. In addition, the optical monitor 26 has an upper surface 26a and a lower surface 26b. The upper surface 26a and the lower surface 26b are surfaces that are positioned on opposite sides in the thickness direction of the optical monitor 26.

The lower surface 25b of the optical amplifier 25 is mounted on the upper surface of a submount 14. The lower surface 26b of the optical monitor 26 is mounted on the upper surface 25a of the optical amplifier 25. That is, the lower surface 25b of the optical amplifier 25 is a mounting surface for the upper surface of the submount 14. The lower surface 26b of the optical monitor 26 is a mounting surface for the upper surface 25a of the optical amplifier 25.

In addition, as depicted in FIG. 6, the optical amplifier 25 has an amplifying stripe 25c, a light emission coupler 25d, a plurality of electrodes 25e and 25f, and a plurality of wiring lines 25g. The amplifying stripe 25 c, the light emission coupler 25d, the plurality of electrodes 25e and 25f, and the plurality of wiring lines 25g are provided on the same surface, which is the upper surface 25a.

The amplifying stripe 25c emits a front laser beam Lf. The light emission coupler 25d emits a rear laser beam Lb. The light emission coupler 25d is connected to the rear end of the elongated amplifying stripe 25c. In this manner, by having the light emission coupler 25d, the optical amplifier 25 can output the rear laser beam Lb from the upper surface 25a. For example, the light emission coupler 25d is a grating coupler.

The electrodes 25e and 25f are arranged around the amplifying stripe 25c and the light emission coupler 25d. Note that the electrodes 25e and 25f are included in laser-side electrodes. In addition, the electrodes 25e are included in wire bonding laser-side electrodes, and the electrodes 25f are included in connection laser-side electrodes.

As described in detail later, the electrodes 25e are arranged in an area not covered with the optical monitor 26 when the optical monitor 26 is mounted on the optical amplifier 25. In addition, the electrodes 25f are covered with the optical monitor 26, and are electrically connected to electrodes 26n of the optical monitor 26 when the optical monitor 26 is mounted on the optical amplifier 25.

The wiring lines 25g electrically connect respective pairs of the electrodes 25e and the electrodes 25f. As described in detail later, the electrodes 25f connected to the wiring lines 25g correspond to electrodes 26n electrically connected to a first photoreceiver 26k and a second photoreceiver 26l in the electrodes 16n of the optical monitor 26.

As depicted in FIG. 6, the optical monitor 26 has a light coupling coupler 26c, an optical splitter 26d, a first optical filter 26e, a second optical filter 26f, a third optical filter 26g, a first heater 26h, a second heater 26i, a third heater 26j, the first photoreceiver 26k, the second photoreceiver 26l, a waveguide mirror 26m, and a plurality of the electrodes 26n. The light coupling coupler 26c, the optical splitter 26d, the optical filters 26e to 26g, the heaters 26h to 26j, the first photoreceiver 26k, the second photoreceiver 26l, the waveguide mirror 26m, and the plurality of electrodes 26n are provided on the same surface, which is the lower surface 26b. In addition, these are connected by optical waveguides (not illustrated).

Note that the optical filters 26e to 26g have the same configuration and the same function. In addition, the heaters 26h to 26j have the same configuration and the same function.

For example, the optical monitor 26 is a reflective filter integrated optical monitor formed by integrating, on a surface of a silicon (Si) substrate, the light coupling coupler 26c, the optical splitter 26d, the optical filters 26e to 26g, the heaters 26h to 26j, the first photoreceiver 26k, the second photoreceiver 26l, the waveguide mirror 26m, the plurality of electrodes 26n, and the optical waveguides.

The light coupling coupler 26c couples the rear laser beam Lb incident perpendicularly on the lower surface 26b of the optical monitor 26, and transmits the rear laser beam Lb to the waveguide mirror 26m via the optical filters 26f and 26g and the heaters 26i and 26j. For example, the light coupling coupler 26c is a grating coupler.

The waveguide mirror 26m transmits part of the rear laser beam Lb transmitted from the light coupling coupler 26c.

The optical splitter 26d receives part of the rear laser beam Lb transmitted from the waveguide mirror 26m, and splits the received part of the rear laser beam Lb into two laser beams.

The first photoreceiver 26k receives a first laser beam obtained by the splitting by the optical splitter 26d, and photo-electrically converts the received first laser beam. In addition, after photo-electrically converting the first laser beam, the first photoreceiver 26k outputs a current corresponding to the optical intensity of the first laser beam. The first photoreceiver 26k functions as an optical power monitor of the optical amplifier 25 because the first photoreceiver 26k converts the optical intensity of the rear laser beam Lb coupled by the light coupling coupler 26c directly into a current. Furthermore, the first photoreceiver 26k is electrically connected to corresponding electrodes 26n. Because of this, it becomes possible for the first photoreceiver 26k to output, to the electrodes 26n, the current corresponding to the optical intensity of the first laser beam.

The first optical filter 26e receives a second laser beam obtained by the splitting by the optical splitter 26d, and transmits the received second laser beam to the second photoreceiver 26l via the first heater 26h.

The second photoreceiver 26l converts a laser beam filtered by the first optical filter 26e (a laser beam resonant with the rear laser beam Lb) into a current. At this time, when the wavelength of the rear laser beam Lb varies, the current value output from the second photoreceiver 26l also varies. In addition, the second photoreceiver 26l is electrically connected to corresponding electrodes 26n. Because of this, it becomes possible for the second photoreceiver 26l to output, to the electrodes 26n, the current corresponding to the optical intensity of the second laser beam.

The electrodes 26n are arranged around the light coupling coupler 26c, the optical splitter 26d, the optical filters 26e to 26g, the heaters 26h to 26j, the first photoreceiver 26k, the second photoreceiver 26l, and the waveguide mirror 26m. The electrodes 26n correspond to the electrodes 25f. Note that the electrodes 26n are included in monitor-side electrodes and connection monitor-side electrodes.

Accordingly, in a case where the optical monitor 26 is mounted on the optical amplifier 25, as depicted in FIG. 6, first, the optical amplifier 25 is oriented in such a manner that the upper surface 25a faces upward, and the optical monitor 26 is oriented in such a manner that the lower surface 26b faces upward. Next, as depicted in FIGS. 6 and 7, from such states, the optical monitor 26 is flipped upside down in such a manner that the upper surface 26a and the lower surface 26b are reversed vertically. Thereby, the lower surface 26b is mounted on the upper surface 25a of the optical amplifier 25.

At this time, the light emission coupler 25d and the light coupling coupler 26c face each other. Because of this, the light coupling coupler 26c can receive and couple the rear laser beam Lb emitted from the light emission coupler 25d. In addition, the electrodes 25f and the electrodes 26n face each other, respectively. The electrodes 25f and the electrodes 26n are joined with each other using gold bumps, solder bumps, or the like. Because of this, the optical module according to the second embodiment can electrically connect the optical amplifier 25 and the optical monitor 26.

Since the optical monitor 26 is mounted in a flipped orientation, wire bonding to the electrodes 26n electrically connected to the first photoreceiver 26k and the second photoreceiver 26l is not possible. That is, a current corresponding to the optical intensity of a laser beam cannot be extracted from the electrodes 26n electrically connected to the first photoreceiver 26k and the second photoreceiver 26l.

However, in the optical module according to the second embodiment, the wiring lines 25g link the electrodes 25f electrically connected to the electrodes 26n and the electrodes 25e not covered with the optical monitor 16. Because of this, the optical module according to the second embodiment can extract a current corresponding to the optical intensity of a laser beam from the electrodes 25e not covered with the optical monitor 26 by bonding wires 30 to the electrodes 25e.

Therefore, the optical module according to the second embodiment can sense the optical output power and oscillation wavelength of the optical amplifier 25 by measuring the current value output from the first photoreceiver 26k and the current value output from the second photoreceiver 26l.

In the optical module according to the second embodiment, the upper surface 25a of the optical amplifier 25 and the lower surface 26b of the optical monitor 26 are connected in such a manner that the upper surface 25a and the lower surface 26b face each other and overlap. Because of this, in the optical module according to the second embodiment, the optical amplifier 25 and the optical monitor 26 can be brought close to each other to within, for example, approximately several tens of μm, without concern for mutual contact. As a result, the optical module according to the second embodiment can enhance the light coupling efficiency of the optical monitor 26, without providing the mounting surface for the optical monitor 26 on a pedestal portion 13.

As described above, the optical module according to the second embodiment includes: the optical amplifier 25 having the light emission coupler 25d to emit the rear laser beam Lb along with the emission of the front laser beam Lf from its front end; and the optical monitor 26 having the light coupling coupler 26c to receive and couple the rear laser beam Lb emitted from the light emission coupler 25d, and the optical amplifier 25 and the optical monitor 26 are superimposed in such a manner that the light emission coupler 25d and the light coupling coupler 26c face each other. Because of this, the optical module according to the second embodiment enables highly efficient coupling of the rear laser beam Lb emitted from the optical amplifier 25 to the optical monitor 26, without providing a mounting surface dedicated for the optical monitor on the pedestal portion 13.

In addition, the optical module according to the second embodiment allows for a reduction in the size and weight of the pedestal portion 13 since the optical amplifier 25 and the optical monitor 26 are connected in such a manner that the optical amplifier 25 and the optical monitor 26 face each other and overlap.

### Third Embodiment

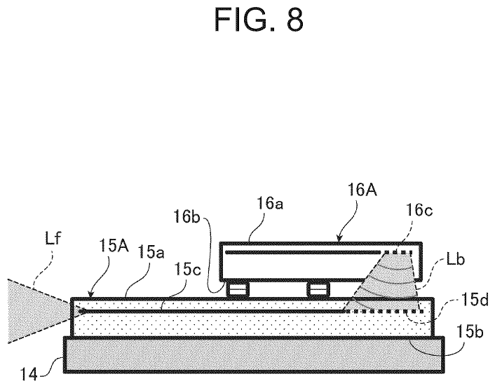

An optical module according to a third embodiment is explained using FIGS. 8 to 10.

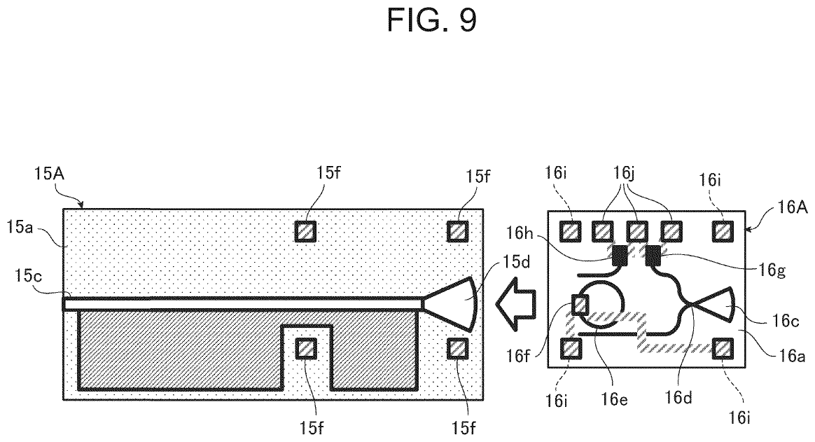

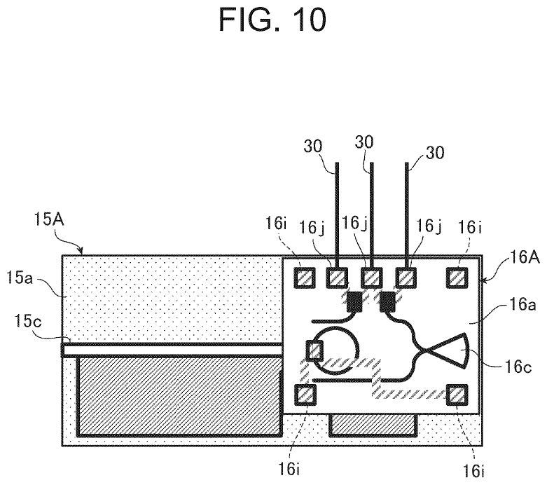

FIG. 8 is an enlarged cross-sectional view of main parts of the optical module according to the third embodiment. FIG. 9 is a plan view of a state before a semiconductor laser 15A and an optical monitor 16A are stacked on each other in the optical module according to the third embodiment. FIG. 10 is a plan view of a state where the semiconductor laser 15A and the optical monitor 16A are stacked on each other in the optical module according to the third embodiment. Note that configurations having functions similar to those of the configurations explained in the first embodiment described above are given identical reference signs, and explanations thereof are omitted.

As depicted in FIG. 8, the optical module according to the third embodiment includes the semiconductor laser 15A and the optical monitor 16A instead of the semiconductor laser 15 and the optical monitor 16 in the optical module according to the first embodiment.

As depicted in FIG. 9, the semiconductor laser 15A has an upper surface 15a, a lower surface 15b, a laser stripe 15c, a light emission coupler 15d, and a plurality of electrodes 15f. The laser stripe 15c, the light emission coupler 15d, and the plurality of electrodes 15f are provided on the same surface, which is the upper surface 15a. The semiconductor laser 15A does not have the electrodes 15e. Note that the upper surface 15a is included in a first surface or a second surface, and the lower surface 15b is included in the second surface or the first surface.

The optical monitor 16A has an upper surface 16a, a lower surface 16b, a light coupling coupler 16c, an optical splitter 16d, an optical filter 16e, a heater 16f, a first photoreceiver 16g, a second photoreceiver 16h, and a plurality of electrodes 16i and 16j. The light coupling coupler 16c, the optical splitter 16d, the optical filter 16e, the heater 16f, the first photoreceiver 16g, the second photoreceiver 16h, and the plurality of electrodes 16j are provided on the same surface, which is the upper surface 16a. The plurality of electrodes 16i are provided on the same surface, which is the lower surface 16b.

The electrodes 16i correspond to the electrodes 15f of the semiconductor laser 15A. That is, the electrodes 15f and the electrodes 16i are connected to each other. The electrodes 16j are electrically connected to the first photoreceiver 16g and the second photoreceiver 16h. Note that the electrodes 16j are included in monitor-side electrodes and wire bonding monitor-side electrodes.

Accordingly, in a case where the optical monitor 16A is mounted on the semiconductor laser 15A, as depicted in FIG. 9, first, the semiconductor laser 15A is oriented in such a manner that the upper surface 15a faces upward, and the optical monitor 16 is also oriented in such a manner that the upper surface 16a faces upward. Next, as depicted in FIGS. 9 and 10, from such states, the optical monitor 16 slides in the lateral direction. Thereby, the lower surface 16b is mounted on the upper surface 15a of the semiconductor laser 15.

At this time, the light emission coupler 15d and the light coupling coupler 16c face each other. Because of this, the light coupling coupler 16c can receive and couple a rear laser beam Lb emitted from the light emission coupler 15d. In addition, the electrodes 15f and the electrodes 16i face each other, respectively. The electrodes 15f and the electrodes 16i are joined with each other using gold bumps, solder bumps, or the like.

Since the optical monitor 16A is mounted not in a flipped orientation, in the optical module according to the third embodiment, wires 30 can be bonded easily to the electrodes 16i that are provided on the upper surface 16a and electrically connected to the first photoreceiver 16g and the second photoreceiver 16h. Because of this, the optical module according to the third embodiment can extract a current corresponding to the optical intensity of a laser beam from the electrodes 15e. That is, the optical module according to the third embodiment can extract a current corresponding to the optical intensity of a laser beam, without using the wiring lines 15g described above.

Therefore, the optical module according to the third embodiment can sense the optical output power and oscillation wavelength of the semiconductor laser 15A by measuring the current value output from the first photoreceiver 16g and the current value output from the second photoreceiver 16h.

In the optical module according to the third embodiment, the upper surface 15a of the semiconductor laser 15A and the lower surface 16b of the optical monitor 16A are connected in such a manner that the upper surface 15a and the lower surface 16b face each other and overlap. Because of this, in the optical module according to the third embodiment, the semiconductor laser 15A and the optical monitor 16A can be brought close to each other to within, for example, approximately several tens of μm, without concern for mutual contact. As a result, the optical module according to the third embodiment can enhance the light coupling efficiency of the optical monitor 16A, without providing the mounting surface for the optical monitor 16A on a pedestal portion 13.

As described above, the optical module according to the third embodiment includes: the semiconductor laser 15A having the light emission coupler 15d to emit the rear laser beam Lb along with the emission of a front laser beam Lf from its front end; and the optical monitor 16A having the light coupling coupler 16c to receive and couple the rear laser beam Lb emitted from the light emission coupler 15d, and the semiconductor laser 15A and the optical monitor 16A are superimposed in such a manner that the light emission coupler 15d and the light coupling coupler 16c face each other. Because of this, the optical module according to the third embodiment enables highly efficient coupling of the rear laser beam Lb emitted from the semiconductor laser 15A to the optical monitor 16A, without providing a mounting surface dedicated for the optical monitor on the pedestal portion 13.

In addition, the optical module according to the third embodiment allows for a reduction in the size and weight of the pedestal portion 13 since the semiconductor laser 15A and the optical monitor 16A are connected in such a manner that the semiconductor laser 15A and the optical monitor 16A face each other and overlap.

### Fourth Embodiment

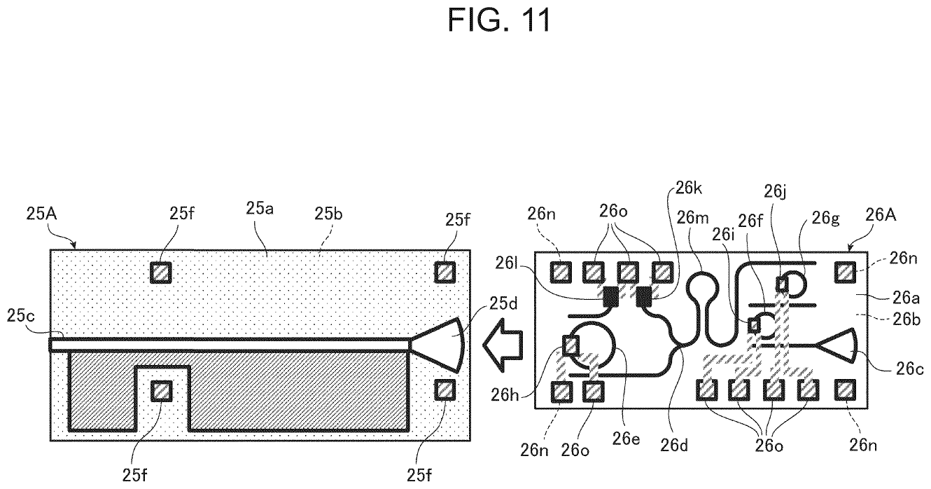

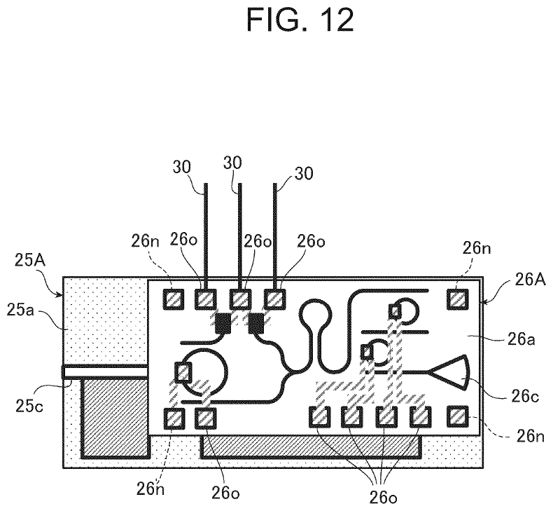

An optical module according to a fourth embodiment is explained using FIGS. 11 and 12.

FIG. 11 is a plan view of a state before an optical amplifier 25A and an optical monitor 26A are stacked on each other in the optical module according to the fourth embodiment. FIG. 12 is a plan view of a state where the optical amplifier 25A and the optical monitor 26A are stacked on each other in the optical module according to the fourth embodiment. Note that configurations having functions similar to those of the configurations explained in the first and second embodiments described above are given identical reference signs, and explanations thereof are omitted.

As depicted in FIG. 11, the optical module according to the fourth embodiment includes the optical amplifier 25A and the optical monitor 26A instead of the optical amplifier 25 and the optical monitor 26 in the optical module according to the second embodiment.

As depicted in FIG. 11, the optical amplifier 25A has an upper surface 25a, a lower surface 25b, an amplifying stripe 25c, a light emission coupler 25d, and a plurality of electrodes 25f. The amplifying stripe 25c, the light emission coupler 25d, and the plurality of electrodes 25f are provided on the same surface, which is the upper surface 25a. The optical amplifier 25A does not have the electrodes 25e. Note that the upper surface 25a is included in a first surface or a second surface, and the lower surface 25b is included in the second surface or the first surface.

The optical monitor 26A has an upper surface 26a, a lower surface 26b, a light coupling coupler 26c, an optical splitter 26d, a first optical filter 26e, a second optical filter 26f, a third optical filter 26g, a first heater 26h, a second heater 26i, a third heater 26j, a first photoreceiver 26k, a second photoreceiver 26l, a waveguide mirror 26m, and a plurality of electrodes 26n and 26o. The light coupling coupler 26c, the optical splitter 26d, the optical filters 26e to 26g, the heaters 26h to 26j, the first photoreceiver 26k, the second photoreceiver 26l, the waveguide mirror 26m, and the plurality of electrodes 26o are provided on the same surface, which is the upper surface 26a. The plurality of electrodes 26n are provided on the same surface, which is the lower surface 26b.

The electrodes 26n correspond to the electrodes 25f of the optical amplifier 25A. That is, the electrodes 25f and the electrodes 26n are connected to each other. The electrodes 26o are electrically connected to the first photoreceiver 26k and the second photoreceiver 26l. Note that the electrodes 26o are included in monitor-side electrodes and wire bonding monitor-side electrodes.

Accordingly, in a case where the optical monitor 26A is mounted on the optical amplifier 25A, as depicted in FIG. 11, first, the optical amplifier 25A is oriented in such a manner that the upper surface 25a faces upward, and the optical monitor 26A is also oriented in such a manner that the upper surface 26a faces upward. Next, as depicted in FIGS. 11 and 12, from such states, the optical monitor 26A slides in the lateral direction. Thereby, the lower surface 26b is mounted on the upper surface 25a of the optical amplifier 25A.

At this time, the light emission coupler 25d and the light coupling coupler 26c face each other. Because of this, the light coupling coupler 26c can receive and couple a rear laser beam Lb emitted from the light emission coupler 25d. In addition, the electrodes 25f and the electrodes 26n face each other, respectively. The electrodes 25f and the electrodes 26n are joined with each other using gold bumps, solder bumps, or the like.

Since the optical monitor 26A is mounted not in a flipped orientation, in the optical module according to the fourth embodiment, wires 30 can be bonded easily to the electrodes 26o that are provided on the upper surface 26a and electrically connected to the first photoreceiver 26k and the second photoreceiver 26l. Because of this, the optical module according to the fourth embodiment can extract a current corresponding to the optical intensity of a laser beam from the electrodes 26o. That is, the optical module according to the fourth embodiment can extract a current corresponding to the optical intensity of a laser beam, without using the wiring lines 25g described above.

Therefore, the optical module according to the fourth embodiment can sense the optical output power and oscillation wavelength of the optical amplifier 25A by measuring the current value output from the first photoreceiver 26k and the current value output from the second photoreceiver 26l.

In the optical module according to the fourth embodiment, the upper surface 25a of the optical amplifier 25A and the lower surface 26b of the optical monitor 26A are connected in such a manner that the upper surface 25a and the lower surface 26b face each other and overlap. Because of this, in the optical module according to the fourth embodiment, the optical amplifier 25A and the optical monitor 26A can be brought close to each other to within, for example, approximately several tens of μm, without concern for mutual contact. As a result, the optical module according to the fourth embodiment can enhance the light coupling efficiency of the optical monitor 26A, without providing the mounting surface for the optical monitor 26A on a pedestal portion 13.

As described above, the optical module according to the fourth embodiment includes: the optical amplifier 25A having the light emission coupler 25d to emit the rear laser beam Lb along with the emission of a front laser beam Lf from its front end; and the optical monitor 26A having the light coupling coupler 26c to receive and couple the rear laser beam Lb emitted from the light emission coupler 25d, and the optical amplifier 25A and the optical monitor 26A are superimposed in such a manner that the light emission coupler 25d and the light coupling coupler 26c face each other. Because of this, the optical module according to the fourth embodiment enables highly efficient coupling of the rear laser beam Lb emitted from the optical amplifier 25A to the optical monitor 26A, without providing a mounting surface dedicated for the optical monitor on the pedestal portion 13.

In addition, the optical module according to the fourth embodiment allows for a reduction in the size and weight of the pedestal portion 13 since the optical amplifier 25A and the optical monitor 26A are connected in such a manner that the optical amplifier 25A and the optical monitor 26A face each other and overlap.

Note that the present disclosure allows for any combination of respective embodiments, modification of any constituent elements in respective embodiments, or omission of any constituent elements in respective embodiments, within the scope of the disclosure.

### Industrial Applicability

The optical modules according to the present disclosure enable highly efficient coupling of the rear laser beam Lb, and are suited for being used as optical modules and the like, since the laser output unit and the optical monitor are superimposed in such a manner that the light emission coupler and the light coupling coupler face each other.

### Reference Signs List

11: Stem; 11a: Main surface; 12: Temperature controller; 12a: Left-side surface; 12b: Right-side surface; 13: Pedestal portion; 13a: Mounting surface; 13b: Vertical surface; 14: Semiconductor laser submount; 15: Semiconductor laser; 15a: Upper surface; 15b: Lower surface; 15c: Laser stripe; 15d: Light emission coupler; 15e, 15f: Electrode; 15g: Wiring line; 16: Planar waveguide type optical monitor; 16a: Upper surface; 16b: Lower surface; 16c: Light coupling coupler; 16d: Optical splitter; 16e: Optical filter; 16f: Heater; 16g: First photoreceiver; 16h: Second photoreceiver; 16i, 16j: Electrode; 17: Thermistor; 18: Cap; 19: Window member; 20: Pin; 25: Optical amplifier; 25a: Upper surface; 25b: Lower surface; 25c: Amplifying stripe; 25d: Light emission coupler; 25e, 25f: Electrode; 25g: Wiring line; 26: Reflective filter integrated optical monitor; 26a: Upper surface; 26b: Lower surface; 26c: Light coupling coupler; 26d: Optical splitter; 26e: First optical filter; 26f: Second optical filter; 26g: Third optical filter; 26h: First heater; 26i: Second heater; 26j: Third heater; 26k: First photoreceiver; 26l: Second photoreceiver; 26m: Waveguide mirror; 26n, 26o: Electrode; 30: Wire; Lf: Front laser beam; Lb: Rear laser beam.

1. An optical module comprising:
a laser outputter having a light emission coupler to emit a rear laser beam along with emission of a front laser beam from a front end; and
an optical monitor having a light coupling coupler to receive and couple the rear laser beam emitted from the light emission coupler, wherein
the laser outputter and the optical monitor are superimposed in such a manner that the light emission coupler and the light coupling coupler face each other.

2. The optical module according to claim 1, wherein
the laser outputter has the light emission coupler and a plurality of laser-side electrodes on the same surface,
the optical monitor has the light coupling coupler and a plurality of monitor-side electrodes on the same surface,
the plurality of laser-side electrodes include:
a plurality of connection laser-side electrodes that are covered with the optical monitor, and are connected to the plurality of monitor-side electrodes, respectively; and
a plurality of wire bonding laser-side electrodes that are not covered with the optical monitor, and are not connected to the plurality of monitor-side electrodes, and
the plurality of wire bonding laser-side electrodes and a plurality of connection laser-side electrodes corresponding to the monitor-side electrodes connected to a photoreceiver of the optical monitor in the plurality of connection laser-side electrodes are connected by wiring lines, respectively.

3. The optical module according to claim 1, wherein
the laser outputter has the light emission coupler and a plurality of laser-side electrodes on the same surface,
the optical monitor has the light coupling coupler and a plurality of monitor-side electrodes, and
the plurality of monitor-side electrodes include:
a plurality of wire bonding monitor-side electrodes that are provided on a surface where the light coupling coupler is disposed, and are connected to a photoreceiver of the optical monitor; and
a plurality of connection monitor-side electrodes that are provided on a surface positioned opposite to the surface where the light coupling coupler is disposed, and are connected to the plurality of laser-side electrodes, respectively.

4. The optical module according to claim 1, comprising:
a stem to support a temperature controller to adjust temperature of the laser outputter and temperature of the optical monitor; and
a cap that has a window member where the front laser beam emitted from the laser outputter is transmitted, and is provided on the stem in such a manner that the cap covers the laser outputter and the optical monitor from outside.
